(19) United States
(12) Patent Application Publication
(10) Pub. No.: US 2010/0150377 A1
(43) Pub. Date: Jun. 17, 2010

(54) SOUND OUTPUTTING APPARATUS TO CORRECT SOUND QUALITY AND METHOD OF CORRECTING SOUND QUALITY THEREOF

(75) Inventor: Jong-taek YOON, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/623,775

(22) Filed: Nov. 23, 2009

(30) Foreign Application Priority Data
Dec. 17, 2008 (KR) 2008-128405

(51) Int. Cl. H03G 5/00

(52) U.S. Cl. 381/98

(57) ABSTRACT

A sound outputting apparatus to correct sound quality and a method of correcting sound quality thereof includes a speaker to output a sound signal, a remaining vibration detector to detect a remaining vibration of the speaker, a signal processor to generate an offset signal for the detected remaining vibration and output a correction signal in which the input sound signal is mixed with the generated offset signal, and a power amplifier to amplify the correction signal and transmit the correction signal to the speaker. Accordingly, sound quality can be corrected without a mechanical damping device.

### CROSS-REFERENCE TO RELATED APPLICATIONS

This application claims priority under 35 U.S.C. §119 (a) from Korean Patent Application No. 10-2008-128405, filed on Dec. 17, 2008, in the Korean Intellectual Property Office, the disclosure of which is incorporated herein by reference in its entirety.

### BACKGROUND

1. Field of the Invention

The present general inventive concept relates to a sound outputting apparatus to correct sound quality and a method of correcting sound quality thereof, and more particularly, to a sound outputting apparatus to correct sound quality, which damps remaining vibration using a feedback circuit, and a method of correcting sound quality thereof.

2. Description of the Related Art

A general woofer outputs an incoming audio signal to a speaker through a volume variator to control the audio signal to have a volume desired by a user, a low pass filter to pass only a low band frequency, and a power amplifier to amplify power required to drive the speaker.

More specifically, the audio signal input to the woofer is controlled to have a desired volume by the volume variator and then is passed through the low pass filter. The low pass filter functions to sound only frequencies of 200 Hz or less of the voice band through the speaker, and also functions to strongly amplify the frequency suitable for the resonant frequency according to the volume of a speaker cabinet. The low band signal filtered by the low pass filter passes through the power amplifier to be converted into power to sound the speaker and drives the speaker.

However, the power amplifier generates high frequency vibrations such as 2nd order or 3rd order vibrations due to its inertia, thereby attenuating the audio signal compared to the original audio signal. Therefore, since the high frequency vibration such as 2nd order or 3rd order vibration affects the next signal, attenuating or increasing the signal, there is a problem in that the original audio signal is distorted.

In order to prevent the distortion of the original audio signal, a mechanical damper may be used. However, if the height of the damper increases, the damper requires a high power amplifier to be normally operated. Therefore, methods for increasing the height of the damper are not cost effective and are limited to a high class speaker unit.

### SUMMARY

The present general inventive concept provides a sound outputting apparatus to correct sound quality which is capable of preventing distortion of sound quality caused by remaining vibration in a speaker using a feedback circuit rather than a mechanical damper, and a method of correcting sound quality thereof.

Additional features and utilities of the present general inventive concept will be set forth in part in the description which follows and, in part, will be obvious from the description, or may be learned by practice of the general inventive concept.

Exemplary embodiments of the present general inventive concept may be achieved by providing a sound outputting apparatus to correct sound quality including a speaker to output a sound signal, a remaining vibration detector to detect a remaining vibration of the speaker, a signal processor to generate an offset signal for the detected remaining vibration and to output a correction signal in which the input sound signal is mixed with the generated offset signal, and a power amplifier to amplify the correction signal and to transmit the amplified correction signal to the speaker.

The sound outputting apparatus may further include a remaining vibration power amplifier to amplify a power of the detected remaining vibration.

The sound outputting apparatus may further include a level adjuster to adjust a level of the sound signal to coincide with a level of the detected remaining vibration.

The sound outputting apparatus may further include a high pass filter to pass only a high band signal of the signal output from the level adjuster and transmit the high band signal to the signal processor.

The speaker may further include an output detection coil to detect vibration caused by a signal output through the speaker.

The offset signal may be an inverted signal of the detected remaining vibration.

Exemplary embodiments of the present general inventive concept may be also achieved by providing a method of correcting sound quality of a sound outputting apparatus having a speaker, the method including outputting a sound signal through the speaker, detecting a remaining vibration of the speaker, generating an offset signal of the detected remaining vibration and outputting a correction signal in which the input sound signal is mixed with the generated offset signal, and amplifying the correction signal and transmitting the correction signal to the speaker.

The method may further include amplifying a power of the detected remaining vibration.

The method may further include adjusting a level of the input sound signal to coincide with a level of the detected remaining vibration.

The method may further include passing only a high band signal including the level-adjusted signal and the detected remaining vibration.

The speaker may further include an output detection coil to detect vibration caused by a signal output through the speaker.

The offset signal may be an inverted signal of the detected remaining vibration.

Exemplary embodiments of the present general inventive concept may also be achieved by providing a sound outputting apparatus to correct sound quality through a speaker, including a remaining vibration detector to detect a remaining vibration of the speaker when the speaker is driven with a sound signal, and a signal processor to generate a correction signal using the detected remaining vibration and to output the correction signal to the speaker to correct the remaining vibration of the speaker.

The apparatus may further comprise a remaining vibration power amplifier to amplify a power of the detected remaining vibration before the signal processor receives the detected remaining vibration.

The apparatus may further comprise a level adjuster to receive the sound signal and the amplified remaining vibration and to adjust a level of the sound signal to coincide with a level of the amplified remaining vibration and to output a leveled signal including the level-adjusted sound signal and the amplified remaining vibration.

The apparatus may further comprise a high pass filter to filter the leveled signal and output a high-pass filtered signal to the signal processor to generate the offset signal.

Exemplary embodiments of the present general inventive concept may also be achieved by providing a method of correcting sound quality in a sound outputting apparatus having a speaker, the method including detecting a remaining vibration of the speaker when the speaker is driven with a sound signal, generating a correction signal using the detected remaining vibration, and outputting the correction signal to the speaker to correct the remaining vibration of the speaker.

The detecting a remaining vibration of the speaker may further comprise transmitting the detected vibration to a remaining vibration detector.

The method may further comprise amplifying a power of the detected remaining vibration.

The method may further comprise adjusting a level of the sound signal to coincide with a level of the amplified remaining vibration and outputting a leveled signal including the level-adjusted sound signal and the amplified remaining vibration.

The method may further comprise high pass filtering the leveled signal and outputting a high-pass filtered signal to generate the offset signal.

Exemplary embodiments of the present general inventive concept may also be achieved by providing a computer-readable medium having executable code stored thereon to perform a method of correcting sound quality in a sound outputting apparatus having a speaker, the method including detecting a remaining vibration of the speaker when the speaker is driven with a sound signal, generating a correction signal using the detected remaining vibration, and outputting the correction signal to the speaker to correct the remaining vibration of the speaker.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a block diagram illustrating a sound outputting apparatus to correct sound quality according to an exemplary embodiment of the present general inventive concept;

FIGS. 2A to 2F are views illustrating input and output signals of each block included in the sound outputting apparatus of FIG. 1; and

FIG. 3 is a flowchart illustrating a method of correcting sound quality according to an exemplary embodiment of the present general inventive concept.

### DETAILED DESCRIPTION OF THE EMBODIMENTS

Reference will now be made in detail to exemplary embodiments of the present general inventive concept, examples of which are illustrated in the accompanying drawings, wherein like reference numerals refer to like elements throughout. The exemplary embodiments are described below in order to explain the present general inventive concept by referring to the figures.

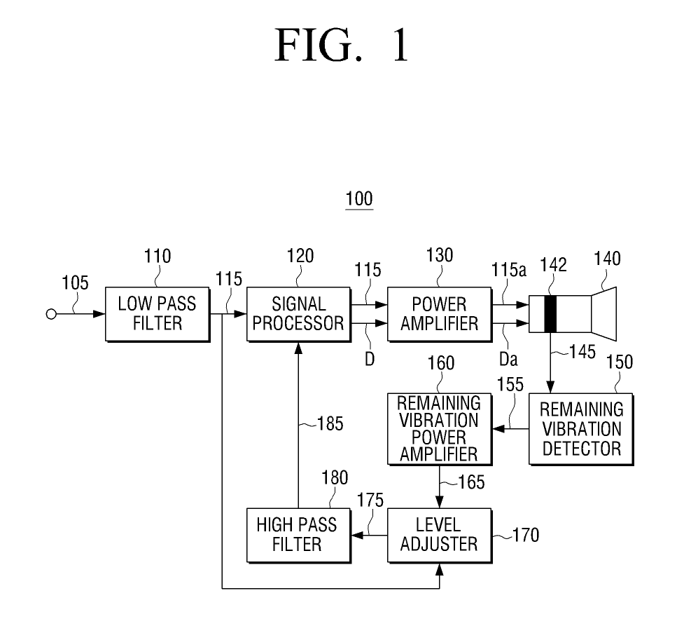

FIG. 1 is a block diagram illustrating a sound outputting apparatus to correct sound quality according to an exemplary embodiment of the present general inventive concept.

Referring to FIG. 1, a sound outputting apparatus 100 to correct sound quality according to an exemplary embodiment of the present general inventive concept includes a low pass filter 110, a signal processor 120, a power amplifier 130, a speaker 140, a remaining vibration detector 150, a remaining vibration power amplifier 160, a level adjuster 170, and a high pass filter 180.

The low pass filter 110 can receive an input signal 105 and can pass only a low band signal of the input signal 105. For example, the low pass filter 110 may be set to pass only frequencies of the input signal 105 ranging from 20 to 200 Hz. The input signal 105 may be an audio signal. The low pass filter 110 can transmit the low band signal 115 to the signal processor 120 and the level adjuster 170.

The signal processor 120 can transmit the low band signal 115 output from the low pass filter 110 to the power amplifier 130. Then, if the signal processor 120 receives a filtered remaining vibration 185 which has been filtered by the high pass filter 180, the signal processor 120 can generate an offset signal C (further described below) for the remaining vibration and can combine the offset signal and the low band signal 115 input from the low pass filter 110, thereby generating a correction signal D (further described below), and can transmit the generated correction signal D to the power amplifier 130.

The power amplifier 130 can amplify power for the low band signal 115 or the correction signal D output from the signal processor 120 to drive the speaker 140. The power amplifier 130 can transmit an amplified low band signal 115a and an amplified correction signal Da to the speaker 140.

The speaker 140 is driven by the power amplifier 130 to output a sound signal. The speaker 140 can generate a complex signal due to the damping effect. The complex signal generated by the speaker 140 includes a fundamental wave which is the same as the input signal 105 input to the low pass filter 110 and a remaining vibration generated in the speaker 140. The remaining vibration is a noise which distorts the original sound signal.

Since the signal output through the speaker 140 when the sound outputting apparatus 100 is initially operated includes the fundamental wave and the remaining vibration, the original sound signal is distorted and output. However, if the correction signal D is input to the speaker 140, the remaining vibration is offset by the correction signal D. By offsetting the remaining vibration, the speaker 140 can output a sound signal which is not distorted.

In general, the speaker 140 outputs a sound signal generated from a vibration of a sound coil unit (not illustrated) and a diaphragm (not illustrated). The sound coil unit is further connected to an output detection coil 142 to detect vibration due to the signal output through the speaker 140. The output detection coil 142 detects a vibration of the diaphragm and can transmit the detected vibration 145 to the remaining vibration detector 150.

If the vibration of the diaphragm is detected by the output detection coil 142 of the speaker 140, the remaining vibration detector 150 can remove the fundamental wave from the signal output through the speaker 140 to detect the remaining vibration and can output the remaining vibration to the remaining vibration power amplifier 160.

The remaining vibration power amplifier 160 can amplify the power for the remaining vibration 155 output from the remaining vibration detector 150 and can transmit the amplified remaining vibration 165 to the level adjuster 170.

The level adjuster 170 can receive the low band signal 115 from the low pass filter 110 and a remaining vibration signal 165 from the remaining vibration power amplifier 160. The level adjuster 170 can adjust the level of the low band signal 115 to coincide with the level of the amplified remaining vibration signal 165.

The high pass filter 180 can receive the signal 175 including the level which has been adjusted by the level adjuster 170, that is, the signal in which the amplified remaining vibration signal 165 is mixed with the level-adjusted fundamental wave (i.e., the low band signal 115), and can pass only the high band portion of the signal, and can transmit the passed signal 185 to the signal processor 120.

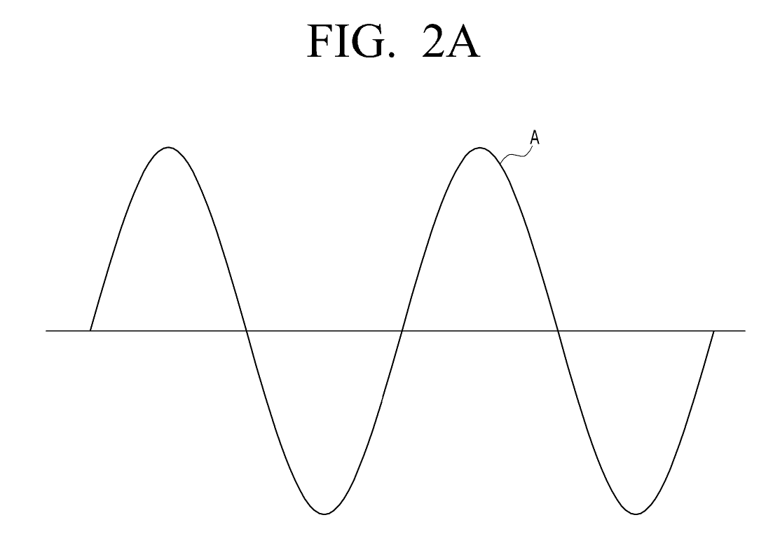

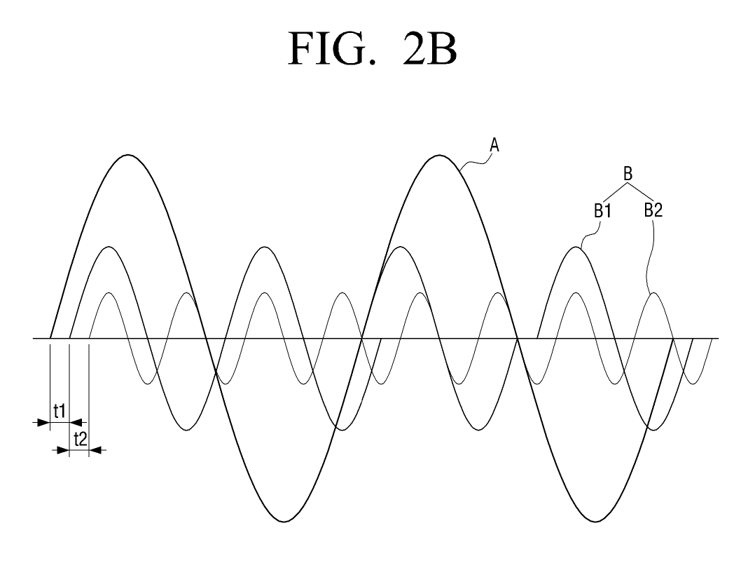

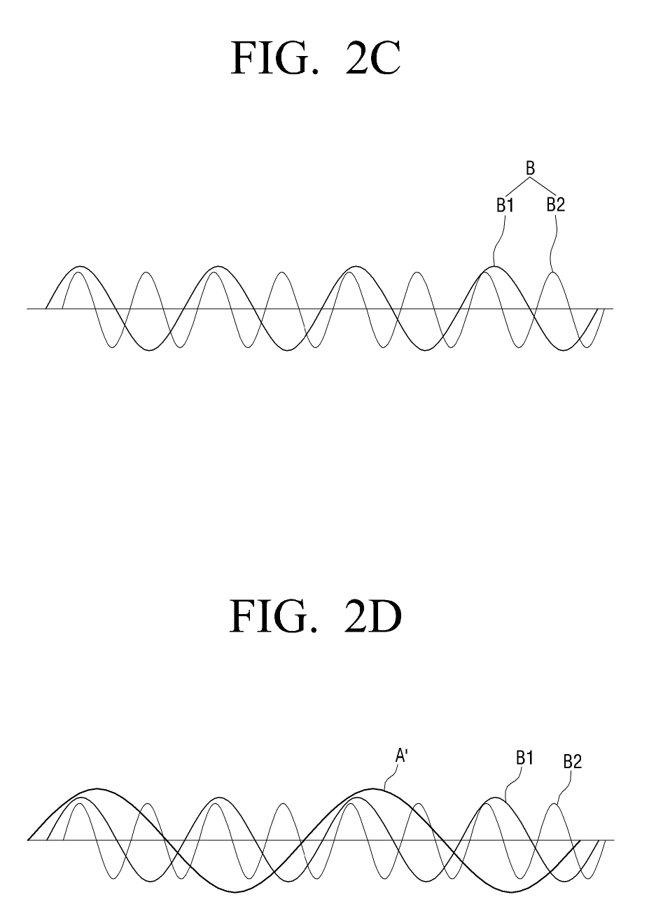

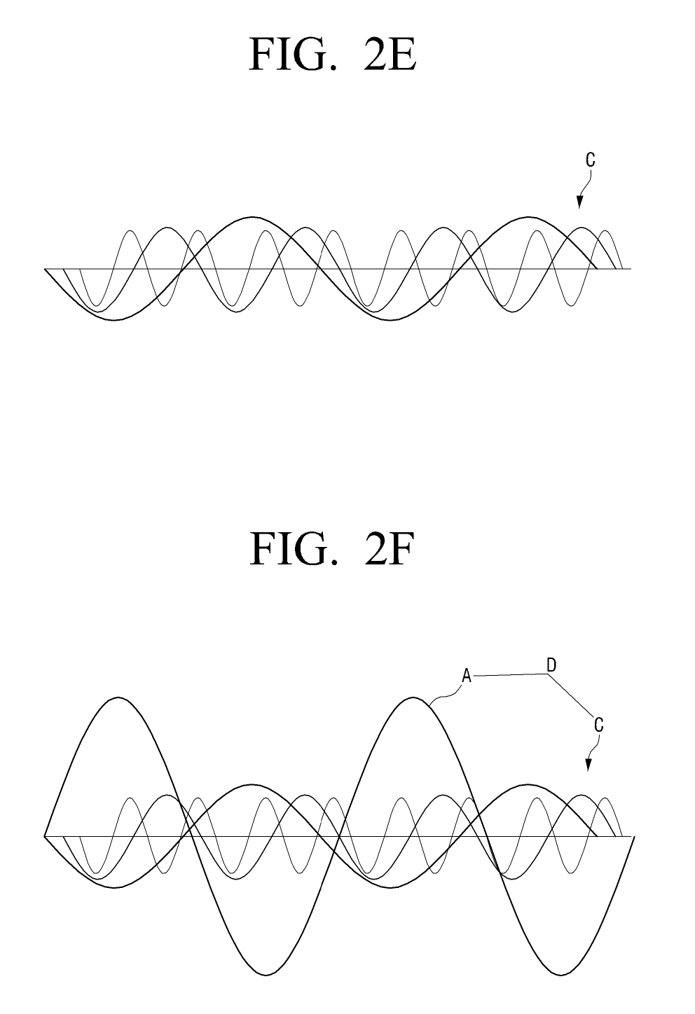

FIGS. 2A to 2F are views illustrating input and output signals of each block included in the sound outputting apparatus illustrated in FIG. 1.

FIG. 2A illustrates an example of a signal, such as input signal 105, which is input to the low pass filter 110. In this example, the input signal input to the low pass filter 110 is referred to as a fundamental wave A. The fundamental wave A is a single signal, not a complex signal containing another signal.

If the fundamental wave A illustrated in FIG. 2A is output from the speaker 140 through the signal processor 120 and the power amplifier 130, a complex signal illustrated in FIG. 2B is generated. Since the speaker 140 generates a high frequency vibration such as a 2nd or 3rd order vibration due to its inertia, gradually attenuating the signal as compared to the original signal received from the power amplifier 130, the vibration such as the 2nd or 3rd order vibration affects the next signal, causing signal distortion attenuating and increasing the original signal.

Thus, the signal output through the speaker 140 generates not only the fundamental wave A which corresponds to the original signal input to the low pass filter 110, but also a remaining vibration B as illustrated in FIG. 2B. Although the speaker 140 can generate 2nd, 3rd, 4th, or higher order vibrations, the 2nd and 4th vibrations are illustrated in FIG. 2B for conciseness.

In FIG. 2B, if, for example, the fundamental wave A is a signal of 200 Hz, then the 2nd order vibration B1 is 400 Hz and the 4th order vibration B2 is 800 Hz. It can be seen in FIG. 2B that there are differences among the times that the fundamental wave A, the 2nd order vibration B1, and the 4th order vibration B2 are generated. That is, a time difference t1 elapses between the generation of the fundamental wave A and the 2nd order vibration B1, and a time difference t2 elapses between the generation of the 2nd order vibration B1 and the 4th order vibration B2. These time differences occur because the 2nd order vibration B1 and the 4th order vibration B2 are generated by a physical vibration of the speaker 140.

If the complex signal including the fundamental wave A and the remaining vibration B is generated in the speaker 140, the remaining vibration detector 150 removes the fundamental wave A from the complex signal as illustrated in FIG. 2B to detect the remaining vibration B. The remaining vibration B detected by the remaining vibration detector 150 is illustrated in FIG. 2C, which corresponds to FIG. 2B with the fundamental wave A removed.

The remaining vibration detected by the remaining vibration detector 150 is input to the level adjuster 170 through the remaining vibration power amplifier 160. The level adjuster 170 receives the remaining vibration B of FIG. 2C and the low band signal 115 passed through the low pass filter 110 and adjusts the level of the low band signal 115 to coincide with the level of the remaining vibration B. As illustrated in FIG. 2D, the level adjuster 170 adjusts the level of the low band signal newly input from the low pass filter 110, indicated in FIG. 2D as a new fundamental wave A′, to coincide with the level of the remaining vibration B.

The signal in which the level of the new fundamental wave A′ is adjusted is transmitted to the signal processor 120 through the high pass filter 180. If the signal processor 120 receives the signal 185 in which the level of the new fundamental wave A′ is adjusted from the high pass filter 180, the signal processor 120 can generate an offset signal C, as illustrated in FIG. 2E, which is an inverted signal of the signal 185 input from the high pass filter 180. After that, the signal processor 120 can mix a new fundamental wave A 115 input from the low pass filter 110 with the offset signal C to generate a correction signal D as illustrated in FIG. 2F. The correction signal D generated by the signal processor 120 can be output from the speaker 140 through the power amplifier 130 as amplified correction signal Da. In the speaker 140, the remaining vibration B is offset by the offset signal C included in the correction signal Da.

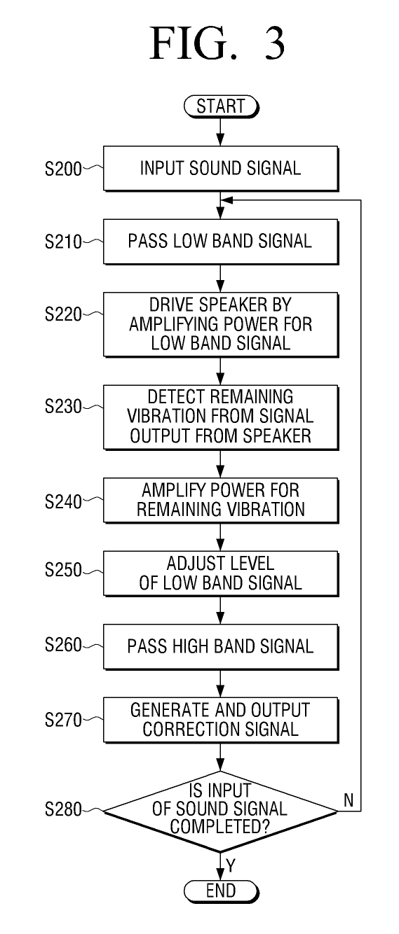

FIG. 3 is a flowchart illustrating a method of correcting sound quality according to an exemplary embodiment of the present general inventive concept.

With reference to FIGS. 1 to 3, the method of correcting sound quality will be described below.

If an input signal 105 is input to the sound outputting apparatus 100 in operation S200, the input signal is input to the low pass filter 110. The input signal 105 is of the fundamental wave A as illustrated in FIG. 2A. Although the input signal 105 may pass through a volume variator to be volume-adjusted prior to being input to the low pass filter 110, such use of a volume variator is well known and thus detailed description thereof is omitted. The fundamental wave A passes through the low pass filter 110 such that only the low band signal 115 is output in operation S210.

The low band signal 115 output from the low pass filter 110 is output to the speaker 140 through the signal processor 120 and the power amplifier 130. The power amplifier 130 amplifies the power of the low band signal to drive the speaker 140 in operation S220.

The speaker 140 is driven by the power amplifier 130 with the amplified fundamental wave A (115a). At this time, remaining vibration is generated in the speaker 140. If the remaining vibration B is detected by the output detection coil 42 of the speaker 140, the remaining vibration detector 150 detects the remaining vibration B by removing the fundamental wave A from the signal 145 output from the speaker 140 in operation S230.

If the remaining vibration B is detected by the remaining vibration detector 150, the remaining vibration power amplifier 160 amplifies the power for the detected remaining vibration B and outputs the amplified remaining vibration 165 in operation S240. The signal 165 output from the remaining vibration power amplifier 160 is transmitted to the level adjuster 170.

The level adjuster 170 receives a new fundamental wave A from the low pass filter 110, and adjusts the level of the new fundamental wave A to form a wave A′ with a level which coincides with the level of the remaining vibration B input from the remaining vibration power amplifier 160 in operation S250.

The signal 175 output from the level adjuster 170 is a signal in which the remaining vibration B is mixed with the level-adjusted new fundamental wave A′, and passes through the high pass filter 180 such that only a high band signal 185 is output in operation S260.

The signal processor 120 receives a new fundamental wave A from the low pass filter 110 and receives the high band signal 185 from the high pass filter 180, in which the remaining vibration B is mixed with the level-adjusted new fundamental wave A′. After that, the signal processor 120 generates an offset signal C which is an inverted signal of the high pass filtered signal 185 in which the remaining vibration B is mixed with the level-adjusted fundamental wave A′, and generates a correction signal D in which the newly input fundamental wave A is mixed with the offset signal C. The correction signal D generated by the signal processor 120 is output through the power amplifier 130 and the speaker 140 in operation S270.

The operations S210 to S270 are repeated until the input of the sound signal to the low pass filter 110 is completed, and finish when the input of the sound signal is completed in operation S280-Y.

The speaker 140 generates remaining vibration B when outputting a sound signal, causing distortion of the original signal. However, according to exemplary embodiments of the present general inventive concept, as the signal output from the speaker 140 is the correction signal D including the offset signal C for the remaining vibration B, the sound signal can be output with the remaining vibration B being offset.

Therefore, it is possible for the sound outputting apparatus 100 to prevent signal distortion which may be caused by 2nd, 3rd, or higher vibration due to the weak damping effect. Also, a mechanical damping device may affect the original signal, whereas the offset signal C which is an inverted signal of the remaining vibration B corrects the output of the speaker 140, thereby minimizing the effect on the original signal and removing the remaining vibration.

The present general inventive concept can also be embodied as computer-readable codes on a computer-readable medium. The computer-readable medium can include a computer-readable recording medium and a computer-readable transmission medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network-coupled computer systems so that the computer-readable code is stored and executed in distributed fashion. The computer-readable transmission medium can transmit carrier waves and signals (e.g., wired or wireless data transmission through the Internet). Also, functional programs, codes, and code segments to accomplish the present general inventive concept can be easily construed by programmers skilled in the art to which the present general inventive concept pertains.

Although certain exemplary embodiments of the present general inventive concept have been illustrated and described, it will be appreciated by those skilled in the art that changes may be made in these exemplary embodiments without departing from the principles and spirit of the general inventive concept, the scope of which is defined in the appended claims and their equivalents.

What is claimed is:

1. A sound outputting apparatus to correct sound quality, comprising:
a speaker to output a sound signal;
a remaining vibration detector to detect a remaining vibration of the speaker;
a signal processor to generate an offset signal for the detected remaining vibration and to output a correction signal in which the input sound signal is mixed with the generated offset signal; and
a power amplifier to amplify the correction signal and to transmit the amplified correction signal to the speaker.

2. The sound outputting apparatus as claimed in claim 1, further comprising:
a remaining vibration power amplifier to amplify a power of the detected remaining vibration.

3. The sound outputting apparatus as claimed in claim 1, further comprising:
a level adjuster to adjust a level of the sound signal to coincide with a level of the detected remaining vibration.

4. The sound outputting apparatus as claimed in claim 3, further comprising:
a high pass filter to pass only a high band signal of the signal output from the level adjuster and transmit the high band signal to the signal processor.

5. The sound outputting apparatus as claimed in claim 1, wherein the speaker further comprises:
an output detection coil to detect vibration caused by a signal output through the speaker.

6. The sound outputting apparatus as claimed in claim 1, wherein the offset signal is an inverted signal for the detected remaining vibration.

7. A method of correcting sound quality of a sound outputting apparatus having a speaker, the method comprising:
outputting a sound signal through the speaker;
detecting a remaining vibration of the speaker;
generating an offset signal of the detected remaining vibration and outputting a correction signal in which the input sound signal is mixed with the generated offset signal; and
amplifying the correction signal and transmitting the correction signal to the speaker.

8. The method as claimed in claim 7, further comprising:
amplifying a power of the detected remaining vibration.

9. The method as claimed in claim 7, further comprising:
adjusting a level of the input sound signal to coincide with a level of the detected remaining vibration.

10. The method as claimed in claim 9, further comprising:
passing only a high band signal including the level-adjusted signal and the detected remaining vibration.

11. The method as claimed in claim 7, wherein the speaker further comprises:
an output detection coil to detect vibration caused by a signal output through the speaker.

12. The method as claimed in claim 7, wherein the offset signal is an inverted signal of the detected remaining vibration.

13. A sound outputting apparatus to correct sound quality through a speaker, comprising:
a remaining vibration detector to detect a remaining vibration of the speaker when the speaker is driven with a sound signal; and
a signal processor to generate a correction signal using the detected remaining vibration and to output the correction signal to the speaker to correct the remaining vibration of the speaker.

14. The apparatus of claim 13, further comprising:
a remaining vibration power amplifier to amplify a power of the detected remaining vibration before the signal processor receives the detected remaining vibration.

15. The apparatus of claim 14, further comprising:
a level adjuster to receive the sound signal and the amplified remaining vibration and to adjust a level of the sound signal to coincide with a level of the amplified remaining vibration and to output an adjusted signal including the level-adjusted sound signal and the amplified remaining vibration.

16. The apparatus of claim 15, further comprising:
a high pass filter to filter the leveled signal and output a high-pass filtered signal to the signal processor to generate the offset signal.

17. A method of correcting sound quality in a sound outputting apparatus having a speaker, the method comprising:
detecting a remaining vibration of the speaker when the speaker is driven with a sound signal;
generating a correction signal using the detected remaining vibration; and
outputting the correction signal to the speaker to correct the remaining vibration of the speaker.

18. The method of claim 17, wherein the detecting a remaining vibration of the speaker further comprises:
transmitting the detected vibration to a remaining vibration detector.

19. The method of claim 17, further comprising:
amplifying a power of the detected remaining vibration.

20. The method of claim 19, further comprising:
adjusting a level of the sound signal to coincide with a level of the amplified remaining vibration and outputting a leveled signal including the level-adjusted sound signal and the amplified remaining vibration.

21. The method of claim 20, further comprising:
high pass filtering the leveled signal and outputting a high-pass filtered signal to generate the offset signal.

22. A computer-readable medium having executable code stored thereon to perform a method of correcting sound quality in a sound outputting apparatus having a speaker, the method comprising:
detecting a remaining vibration of the speaker when a sound signal is input to the speaker;
generating a correction signal using the detected remaining vibration; and
outputting the correction signal to the speaker to correct the remaining vibration of the speaker.
